(19) United States
(12) Patent Application Publication
(10) Pub. No.: US 2007/0262426 A1
(43) Pub. Date: Nov. 15, 2007

(54) Semiconductor Housings Having Coupling Coatings

(76) Inventor: Joachim Mahler, Regensburg (DE)

Correspondence Address: Steven e Dicke;Dicke Billig & Czaja, Suite 2250 Fifth Street Towers, 100 South Fifth Street, Minneapolis, MN, 55402, US

(21) Appl. No.: 10/587,435

(22) PCT Filed: Jan. 26, 2005
(86) PCT No.: PCT/DE05/00112

§ 371 Date: May 15, 2007

(30) Foreign Application Priority Data
Jan. 27, 2004 (DE) 10 2004 004 231.4
Mar. 18, 2004 (DE) 10 2004 013 732.3

(51) Int. Cl. H01L 23/495; H01L 21/60

(52) U.S. Cl. 257/669; 257/783; 438/118; 257/E23.04; 257/E21.51

(57) ABSTRACT

A semiconductor housing having a coupling coating is disclosed. In one embodiment, the semiconductor housing includes a leadframe for equipping with a semiconductor chip and for enveloping with a polymer material, to which a polymer layer has been applied. The polymer layer has end groups which possess particularly good adhesion to the polymer material or the surface of the flat conductor.

### BACKGROUND

One aspect of the invention relates to a flat conductor or to the basic structure thereof for a semiconductor component with coated surface, which enables improved adhesion of polymer materials in semiconductor housings. To coat the flat conductor, an organic polymer is used.

In semiconductor components, inadequate adhesion between metallic flat conductor and polymer material leads to moisture accumulating in the interface between flat conductor and polymer material. This expands abruptly when the semiconductor component attains temperatures of up to 260° C. very briefly in the course of soldering to a conductor plate. The consequence of the abrupt expansion is cracks and/or fractures in the polymer encapsulation of the semiconductor component, which is referred to as the “popcorn effect”.

In order to prevent this popcorn effect, the accumulation of moisture in the adhesive-bonded joint, i.e. in the interface between flat conductor and polymer encapsulation, must be prevented. The accumulation of moisture is reduced by improving the adhesion between the surface of the flat conductor and the surface of the polymer material.

There are various approaches to improving this adhesion. U.S. Pat. No. 5,554,569 discloses a process for mechanically roughening the surface of a leadframe. The roughened surface enables better interlocking with the polymer material and hence better adhesion. However, this process is difficult to perform.

U.S. Pat. No. 5,554,569 also reports silanes as adhesion promoters for improving the adhesion between flat conductor and polymer encapsulation, but mentions at the same time that the use of silanes is not advisable for a wide variety of reasons.

Another approach is known from U.S. Pat. No. 5,122,858. The adhesion between metallic flat conductor and polymer encapsulation is improved by coating the flat conductor with a polymer which possesses good adhesion properties both with regard to the flat conductor and with regard to the polymer encapsulation. Possible adhesion promoters proposed are the following substances: polyimides, epoxides, acrylics, urethanes, benzotriazoles, benzothiazoles, mercapto esters or thioesters, 5-carboxybenzotriazole, 5-(1-aminoethylamido)benzotriazole, 5-amidobenzotriazole, ethylene-vinyl acetate, refractory oxides, matt nickel plating, phosphates and polymers.

Even though a multitude of processes which serve to improve the adhesion between flat conductor and polymer encapsulation are known in the prior art, the improvements achieved to date are insufficient to completely prevent the popcorn effect, so that there is still a need to reliably prevent accumulation of moisture in the adhesive-bonded joint between flat conductor and polymer encapsulation.

In addition, there is a need for an adhesion promoter which does not decompose as the encapsulated semiconductor component is soldered in, i.e. at temperatures of up to approx. 260° C., in order thus to ensure adhesion between polymer material and flat conductor even after installation.

It is also desirable that the adhesion promoter can also be used as an adhesion promoter between polymer material and other materials, for example a semiconductor chip or a ceramic substrate or the like.

For these and other reasons, there is a need for the present invention.

### SUMMARY

In one embodiment, the present invention provides a novel process which generates reliable adhesion between a polymer and a further material, for example a metal or a ceramic or another polymer.

### BRIEF DESCRIPTION OF THE DRAWING

The accompanying drawings are included to provide a further understanding of the present invention and are incorporated in and constitute a part of this spedcification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross section through an inventive semiconductor component with coated substrate.

FIG. 2 illustrates a cross section through an inventive semiconductor component with full coating of all components.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one embodiment, the invention provides a leadframe which is intended to be equipped with a semiconductor chip and to be enveloped with a polymer material. A polymer layer is disposed on the leadframe as an adhesive layer. The polymer layer has end groups which are aligned toward the polymer material. In addition, the polymer layer has end groups which are aligned toward the flat conductor. Furthermore, the polymer layer includes at least one polymer from the group of the fluorinated polyimides, the polyamide imides or the polyimide-silicone copolymers having silanes in the copolymer chain.

In a first embodiment, the invention provides a substrate with a coated surface which offers highly improved adhesion for the enveloping polymer encapsulation in a semiconductor component.

In the present text, “substrate” refers to a series of different materials, for example ceramic or organic materials or metals such as copper. The material of the substrate is guided by the planned use, or by the type of semiconductor component to be produced. For example, PGA (pin grid array) components have ceramic substrates, flip chip components have organic substrates with electrically conductive regions and high-performance semiconductor components or else diodes have metallic substrates, or flat conductors.

Even though the present invention is intended primarily as an adhesion promoter between a polymer composition and a metallic substrate, it is nevertheless possible and conceivable to use this adhesion promoter for other material combinations, or as an adhesion promoter between a polymer and a nonmetallic substrate.

In a further embodiment of the present invention, not only the substrate itself is treated with the adhesion promoter, but rather the entire semiconductor component, i.e. substrate, semiconductor chip and electrical contacts, is coated selectively with the adhesion promoter before the polymer composition is applied, excluding the outer connecting pins.

According to one embodiment of the present invention, the adhesion between a substrate or an unencapsulated semiconductor component and the polymer material is improved when the substrate or the unencapsulated semiconductor component is coated in accordance with the process described below with the polymers or substances which are likewise described below.

Even though coating of unencapsulated semiconductor components is unusual, since treatment of the finished semiconductor chip with ion-containing solutions is conventionally dispensed with in order to prevent penetration of ions into active semiconductor chip structures and hence shifting of electrical parameters up to and including failures, the experiments carried out here have illustrated that there have been no failures in the semiconductor chips owing to only minimal ionic contaminations in the correspondingly specified coating substances used—fraction of hydrolyzable ion-forming substances in the lower ppm range.

The basic concept of the present invention is to provide a substrate or an unencapsulated semiconductor component with a coated surface, whose composition meets the need for improved adhesion between polymer material and substrate, or unencapsulated semiconductor component.

It is also common to all inventive substances that they are thermally stable at least up to approx. 235° C., in some cases up to approx. 245° C. and in part up to approx. 260° C.

“Thermally stable” means here that the adhesion promoter in the finished semiconductor component can be exposed to these temperatures without noticeable decomposition for periods as typically occur as the semiconductor component is soldered in.

This thermal stability is an advantage of the present invention with regard to the use of lead-free solder materials. Owing to the material, lead-free solders require higher soldering temperatures, so that the temperature as the semiconductor component is soldered onto a circuit board can rise to approx. 260° C.

The substances for coating are selected such that the resulting polymer layer has specific end groups on the side facing toward the polymer material, which have a particular affinity for the polymer material selected. On the side facing toward the flat conductor, the polymer layer has end groups which have a particular affinity for the corresponding material of the substrate, i.e., for example, for copper.

The substances for coating disclosed in the present invention also not only have good adhesion for copper but also for the semiconductor chip material Si, for the semiconductor chip metalization Al, for the materials of the semiconductor chip passivation and insulation SiO₂, Si₃N₄ and/or polyimide, and for coatings such as Ag and Ni, or Ni/NiP, Au and Pd.

The way in which the coating is applied to the surface of the flat conductor and the time of application are guided by the requirements of the corresponding semiconductor component and do not have a restrictive effect on the selection of the substances used for the coating.

Before or after the securing of the semiconductor chip, the substrate is coated with the inventive substance. This is advantageous since the coating process can be accommodated into the manufacturing process at various points according to the needs or requirements of the semiconductor component to be produced.

In a second embodiment of the present invention, it is thus possible to coat the unencapsulated semiconductor component with the inventive polymer before the application of the polymer material. This has the further advantage that not only the adhesion between substrate and polymer material but also between polymer material and semiconductor chip is improved, which may be of significance in particular in the case of large-surface area semiconductor chips depending on the type and use of the semiconductor component.

The conventional, selective coating only of the substrate and not of the entire unencapsulated semiconductor component, in contrast, has the following disadvantages:

As a result of the better adhesion of the polymer material to the substrate, increased stress results in detachments at the next-weakest interface, usually at the semiconductor chip surface and the polymer material, which entails a higher risk of failure than the detachment between polymer material and substrate owing to the wire contact and the metalization present on the semiconductor chip surface.

Selective coating also has the disadvantage that no coating can be effected directly onto the regions for the wire contacting on the pins and on the chip island, which has been developed and designed for a maximum chip size, which in turn entails locally weaker interfaces.

According to one embodiment of the present invention, the substance for coating includes polymers and/or polymer precursors or monomers with precisely defined functional groups selected on the basis of their chemical and physical properties.

In addition, it is conceivable and possible that the inventive substance is a suspension and includes additives such as solvents, adhesion promoters, antioxidants, catalysts, reinforced fillers, plasticizers and/or UV stabilizers. It is also possible that the substance includes copolymers.

The coating of the substrate or of the unencapsulated semiconductor component with the inventive substance can be done in a wide variety of ways, for example by immersion, spraying, dripping or by template printing.

The addition of solids and/or the use of copolymers enables further properties, for example long life or a certain mechanical strength, to be imparted to the substance, and hence the substance to be optimized for the desired use and/or the desired method of coating.

The way in which the coating is applied is guided by whether the entire substrate or only certain parts thereof or the unencapsulated semiconductor component is to be coated. This is advantageous since the method of application can be selected taking account of boundary conditions which are predefined by the type of semiconductor component to be produced.

When, for example, only certain parts of a substrate are to be coated, it is advantageous when the coating is applied by means of template printing. When, in contrast, the entire substrate and/or the unencapsulated semiconductor component are to be coated, an immersion coating process may be advantageous.

In addition, the method of application may also be guided, for example, by the viscosity of the substance used for coating and/or the desired coating thickness. This means that the substance to be applied can be selected without restriction by the method of application.

After the application of the precursor, the inventive polymer layer is obtained either by evaporating the solvent required for application or by crosslinking the polymer precursor applied, for example by means of thermal or UV curing, to give the polymer.

The resulting, cured polymer layer is very thin and ideally has a layer thickness of from approx. 50 nm to approx. 5 μm and preferably a thickness of from approx. 0.5 μm to approx. 5 μm.

In a particular embodiment of the invention, the adhesive layer includes a fluorinating polyimide. To this end, a 10 percent by weight solution of a polyimide, composed of 2,2-bis[phenyl-3′,4′-dicarboxylic anhydride]-1,1,1,3,3,3-hexafluoropropylene and 3,3′,5,5′-tetramethyl-4-,4′-diaminodiphenylmethane in γ-butyrolactone or NMP and cyclopentanone with a γ-butyrolactone or NMP:cyclopentanone weight ratio=1:2, is sprayed onto the semiconductor component before the encapsulation process, selectively without spraying of the outer connecting pins and of the heatsink plate, with a suitable dispensing apparatus, in such a way that a layer thickness d where 0.05 μm≦d≦5 μm is realized after the heat treatment process which follows, preferably 0.05 μm≦d≦5 μm.

The composition of this preferred adhesive layer has the advantage that the adhesion between the coated surfaces and the polymer coating is achieved by the very high interaction of the negatively electrically charged fluorine atoms of the polyimide with the coated, partially positively charged surfaces, while the adhesion between the adhesive layer and the epoxy resin molding material is advantageously achieved by formation of an interpenetrating network owing to the interdiffusion between the polyimide chains and the epoxy resin prepolymers.

In a further preferred embodiment of the invention, the adhesive layer includes a polyamide imide having silanes in the polymer chain. To this end, a 20 percent by weight solution of polyamide imide (PAI) in dimethylacetamide, NMP or γ-butyrolactone is admixed with from 0.1 to 1 percent by weight of 3-aminopropyltrimethoxysilane, and stirred at 80° C. for 2 hours. In the course of this, the amino groups of the silane condense with the acid groups of the PAI, and in such a way that, depending on the amount of the silane added, approx. every 2nd to 10th free acid group of the PAI has reacted chemically with an amino group of a silane. The solution thus obtained can then be diluted in any desired manner with cyclopentanone, anisole, acetone or similar solvents to a concentration of approx. 5 percent by weight based on the silane-modified PAI. This solution is sprayed onto the semiconductor component before the encapsulation process, selectively without spraying of the outer connecting pins and of the heatsink plate, with a suitable dispensing apparatus, in such a way that a layer thickness d of 0.05 μm≦d≦5 μm is realized after a heat treatment process which follows, preferably 0.5 μm≦d≦5 μm.

The adhesive layer realized has the advantage that the adhesion between the coated surfaces and the polymer coating is achieved both as a result of the reaction of the hydrated methoxy groups of the silane bonded to the PAI with the oxides or hydrated oxides of the surfaces, and as a result of the interaction of the acid groups of the PAI with the surfaces, while the adhesion between the coating and the epoxy resin molding material is advantageously achieved by the formation of an interpenetrating network owing to the interdiffusion between the polyamide imide chains and the epoxy resin prepolymers.

In a further embodiment of the invention, the adhesive layer preferably includes a polyimide-silicone copolymer having silanes in the polymer chain. To this end, a 20 percent by weight solution of polyamide imide (PAI) in dimethylacetamide, NMP or γ-butyrolactone is admixed with from 0.1 to 1 percent by weight of 3-aminopropyltrimethoxysilane, and stirred at 80° C. for 2 hours. In the course of this, the amino groups of the silane condense with the acid groups of the PAI, and in such a way that, depending on the amount of silane added, approx. every 2nd to 10th free acid group of the PAI has reacted chemically with an amino group of a silane. Such a polymer which has been reacted with silanes and is composed of silicone and polyamide imide is sprayed as an approx. 5 percent by weight solution in NMP, cyclopentanone and acetone with a mass ratio of the solvents: NMP:cyclopentanone:acetone=approx. 1:2:2 onto the semiconductor component before the encapsulation process, selectively without spraying of the outer connecting pins and of the heatsink plate, with a suitable dispensing apparatus, in such a way that a layer thickness d of 0.05 μm≦d≦5 μm is realized after the heat treatment process which follows, preferably 0.5 μm≦d≦5 μm.

The adhesive layer thus realized has the advantage that the adhesion between the coated surfaces and the polymer coating is achieved both by the reaction of the hydrated methoxy groups of the silane bonded to the PAI with the oxides or hydrated oxides of the surfaces, and by the interaction of the acid groups of the PAI with the surfaces, while the adhesion between the coating and the epoxy resin molding material is advantageously achieved by the formation of an interpenetrating network owing to the interdiffusion between the polyamide imide chains and the epoxy resin prepolymers. The silicone structures in the polymer chain facilitate the interdiffusion process, especially because they greatly increase the mobility of the polymer chain. Moreover, the moisture absorption of the coating polymer is advantageously significantly reduced by the silicone structures, which in turn greatly increases the reliability of the polymer coating with respect to later stress tests with moisture in the case of preconditioning storage before the components are soldered onto the circuit board or in the case of autoclave storage.

The application of the inventive substance can be done either before the securing of the semiconductor chip on the substrate and before the contacting, or thereafter.

It is advisable when substances which are applied to selected points in a template printing process are applied on the substrate actually before the semiconductor chip is secured and before the contacting, because damage and/or contamination of the semiconductor chip and/or of the contacts by the application process are prevented in this way.

When the inventive substance is applied over the whole surface, it is advantageous to perform this after the securing of the semiconductor chip and the contacting, because the surface of the flat conductor is available unchanged in this way for the securing and contacting process.

According to the present invention, for the treatment of the substrate or of the unencapsulated semiconductor component, preference is given to the following end polymers and/or formulations which include these end polymers either as a precursor and/or directly: polyimides, polyurethanes, epoxides, polyisocyanates, liquid-crystalline polymers, high-temperature-resistant thermoplastics, phenol resins, unsaturated polyesters, amino resins, silicones and all polymers which have sulfur in the main chain or the side chain, for example polyphenylene sulfides, polyether sulfones.

In addition, the polymer layer may additionally have, in the main chains and/or side chains, one or more of the following functional groups: sulfone group, mercapto group, amino group, carboxyl group, cyano group, keto group, hydroxyl group, silano group and/or titano group, and/or mixtures thereof.

The polymer precursor may also include a mixture of two or more of the polymers mentioned here. In addition, it is possible that the polymer layer has one or more plies, each ply comprising one or more of the polymers mentioned here.

A multi-ply coating has the advantage that each ply may have different properties. For example, the first ply ideally has good adhesion to metals, semiconductors, polymers and ceramic oxides and nitrides, and also to a further layer applied thereto. At least one further ply is then applied to this ply and has a high adhesion both to the first ply and to the polymer composition. In addition, the possibility exists of incorporating buffer layers with, for example, particular mechanical properties.

Particularly suitable in accordance with the present invention are polybenzoxazoles, polybenzimidazoles, long-chain silanes and imidazoles.

The production of an inventive semiconductor component is illustrated below with reference to three examples:

### EXAMPLE 1

With use of a fluorinated polyimide, first a 10 percent by weight solution of a polyimide, composed of 2,2-bis[phenyl-3′,4′-dicarboxylic anhydride]-1,1,1,3,3,3-hexafluoropropylene and 3,3′,5,5′-tetramethyl-4,4′-diaminodiphenylmethane in γ-butyrolactone (or NMP) and cyclopentanone in a γ-butyrolactone (or NMP): cyclopentanone weight ratio=1:2, is sprayed onto the semiconductor component before the encapsulation process, selectively without spraying of the outer connecting pins and of the heatsink plate, with a suitable dispensing apparatus in such a way that a layer thickness d where 0.05 μm≦d≦5 μm is realized after the heat treatment process which follows, preferably 0.5 μm≦d≦5 μm. The component thus coated is heated from room temperature to 200° C. in an oven with rapid nitrogen purging using a temperature ramp (2-5° C./min) and kept at 200° C. for 60 minutes in order to evaporate the solvents out of the coating solution. After cooling the component to room temperature, the adhesion-promoting coating is complete and the component can be coated with the encapsulating material composed of epoxy resin in the next process.

The adhesion between the coated surfaces and the polymer coating is achieved here by the very high interaction of the negatively electrically charged fluorine atoms of the polyimide with the coated, partially positively charged surfaces, while the adhesion between the coating and the epoxy resin molding material is advantageously achieved by the formation of an interpenetrating network owing to the interdiffusion between the polyimide chains and the epoxy resin prepolymers.

### EXAMPLE 2

In a second example, a polyamide imide having silanes in the polymer chain is used for an adhesive layer. To this end, in a dimethylacetamide, NMP or γ-butyrolactone, a 20 percent by weight solution of polyamide imide (PAI) is admixed with from 0.1 to 1 percent by weight of 3-aminopropyltrimethoxysilane and stirred at 80° C. for 2 hours. In the course of this, the amino groups of the silane condense with the acid groups of the PAI, and in such a way that, depending on the amount of silane added, approx. every 2nd to 10th free acid group of the PAI has reacted chemically with an amino group of a silane. The solution thus obtained is then diluted in any desired manner with cyclopentanone, anisole, acetone or similar solvents to a concentration of approx. 5 percent by weight (based on the silane-modified PAI). This solution is applied to the semiconductor component before the encapsulation process selectively (without coating of the outer connecting pins and of the heatsink plate on which a semiconductor chip is later to be arranged) with a suitable dispensing apparatus in such a way that a layer thickness d where 0.05 μm≦d≦5 μm is realized after the heat treatment process which follows, preferably 0.5 μm≦d≦5 μm.

The component thus coated is heated from room temperature to 200° C. in a nitrogen-purged oven using a temperature ramp (2-5° C./min) and kept at 200° C. for 60 minutes in order to evaporate the solvents out of the coating solution. After the component has been cooled to room temperature, the adhesive-promoting coating is complete and the component can be enveloped with the encapsulating material composed of epoxy resin in the next process.

The adhesion between the coated surfaces and the polymer coating is achieved here both by the reaction of the hydrated methoxy groups, of the silane bonded to the PAI, with the oxides or hydrated oxides of the surfaces, and by the interaction of the acid groups of the PAI with the surfaces, while the adhesion between the coating and the epoxy resin molding material is advantageously achieved by the formation of an interpenetrating network owing to the interdiffusion between the polyamide imide chains and the epoxy resin prepolymers.

### EXAMPLE 3

For a third example, a polyimide-silicone copolymer having silanes in the polymer chain is used. To this end, a polymer which has been reacted with silanes according to Example 2 and is composed of silicone and polyamide imide, as an approx. 5 percent by weight solution in NMP, cyclopentanone and acetone in a mass ratio of the solvents: NMP:cyclopentanone:acetone at approx. 1:2:2, is applied to the semiconductor component before the encapsulation process, selectively without coating of the outer connecting pins and of the heatsink plate, with a suitable dispensing apparatus in such a way that a layer thickness d where 0.05 μm≦d≦5 μm is realized after the heat treatment process which follows, preferably 0.5 μm≦d≦5 μm. The component thus coated is heated from room temperature to 200° C. in a nitrogen-purged oven using a temperature ramp (2-5° C./min) and kept at 200° C. for 60 minutes in order to evaporate the solvents out of the coating solution. After the component has been cooled to room temperature, the adhesion-promoting composition is complete and the component can be enveloped with the encapsulating material composed of epoxy resin in the next process.

The adhesion between the coated surfaces and the polymer coating or adhesion coating is achieved both by the reaction of the hydrated methoxy groups, of the silane bonded to the PAI, with the oxides or hydrated oxides of the surfaces, and by the interaction of the acid groups of the PAI with the surfaces, while the adhesion between the coating and the epoxy resin molding material is advantageously based on the formation of an interpenetrating network owing to the interdiffusion between the polyamide imide chains and the epoxy resin prepolymers.

The silicone structures in the polymer chain facilitate this interdiffusion process, since they greatly increase the mobility of the polymer chain. Moreover, the moisture absorption of the coating polymers is advantageously significantly reduced by the silicone structures, which in turn greatly increases the reliability of the polymer coating with respect to later stress tests with moisture, for example in the case of preconditioning storage before the components are soldered onto the circuit board or in the case of autoclave storage.

### EXAMPLE 4

A polyamidocarboxylic acid (polycondensed from the monomers pyromellitic anhydride and 4,4′-oxydianiline) dissolved in from approx. 50 to approx. 90% by weight of N-methylpyrrolidone (NMP) and esterified with diethylene glycol methacrylate is diluted with cyclopentanone in a ratio of approx. 1:20. For better applicability and wettability of the surfaces to be treated, the solution thus prepared is mixed further with acetone or ethanol in a ratio of approx. 1:1.

After contact connection with the semiconductor chip and wires, the still unencapsulated semiconductor component is immersed into this solution at an immersion rate of from approx. 0.5 to approx. 5 cm per second and pulled out again. Subsequently, the semiconductor component thus coated is treated in a magazine at about room temperature for from approx. 5 to approx. 500 minutes, in order to allow the acetone or ethanol and parts of the cyclopentanone and NMP₃ to evaporate off. Thereafter, to evaporate the residual cyclopentanone and NMP with elimination of the diethylene glycol methacrylate, this semiconductor component in the magazine is introduced for from approx. 15 to approx. 60 minutes in a forced-air oven with a set temperature of from approx. 80 to approx. 100° C., in the course of which the oven is purged with at least approx. 20 l/min of nitrogen in order to substantially suppress or significantly slow oxidation processes. The temperature is then increased to approx. 250° C. with a heating rate of from approx. 3 to approx. 5° C./min and is kept for at least approx. 60 minutes for conversion (imidization) of the polyamidocarboxylic acid to the polyimide. At the same time, the chemical reaction of the polymer with the particular surfaces is enhanced at this temperature.

After cooling (cooling rate from approx. 2 to approx. 5° C./min) of the coated semiconductor component in the oven with nitrogen purging to about room temperature, the semiconductor components thus coated are encapsulated with an epoxy resin molding material within approx. 48 hours. In the subsequent processes of molding material removal in a high-pressure water jet (“water-jet deflashing”) on the unencapsulated pins, and also on the hotplate, and the activation of the connecting pins and of the hotplate for the application of the solderable metalization (“solder plating”), the coating can be removed again in the unencapsulated region.

### EXAMPLE 5

The solution, described under Example 4, of the polyamidocarboxylic ester in the NMP/cyclopentanone/acetone mixture is admixed with approx. 10% (based on the weight of pure polyamidocarboxylic ester) of N-(3-(trimethoxysilyl)propyl)ethylenediamine and stirred at approx. 120° C. for approx. one hour. In the course of this, the silane is polycondensed first with another silane to give the silicone and, simultaneously with its amino group, partly with the acid groups of the polyamidocarboxylic acid to form the polyamide-silicone block copolymer, and secondly, together with its amino group, partly with the acid groups of the polyamidocarboxylic acid, once the diethylene glycol methacryloyl side chains have been eliminated, to give the silane- or silicone-modified polyimide precursor.

Into this solution thus prepared, after the contacting with the semiconductor chip and wire, the still unencapsulated semiconductor component is sprayed with a spray apparatus in such a way that, after the baking-out, which takes place under exactly the same conditions as in Example 4, a mean layer thickness of from approx. 0.2 to approx. 1 μm has formed. The regions of the component which are not to be encapsulated are selectively covered with a steel or Teflon mask, so that no areas or only minimal areas of coating are present on these regions after curing (flow of the solution away from the sprayed region). Subsequently, the component thus coated is stored in a magazine at about room temperature for from approx. 5 to approx. 500 minutes, in order to allow the acetone and parts of the cyclopentanone, and of the NMP to evaporate off. Thereafter, to evaporate the residual cyclopentanone and NMP with elimination of the diethylene glycol methacrylate, this component in the magazine is introduced for from approx. 15 to approx. 60 minutes into a forced-air oven with a set temperature of from approx. 80 to approx. 100° C., the oven being purged with at least approx. 20 l/min of nitrogen in order to substantially suppress or significantly prolong oxidation processes. The temperature is then increased to approx. 250° C. with a heating rate of from approx. 3 to approx. 5° C./min and is kept for at least approx. 60 minutes for conversion (“imidization”) of the polyamidocarboxylic acid to the polyimide. At the same time, the chemical reaction of the polymer with the particular surfaces is enhanced at this temperature. After cooling (cooling rate from approx. 2 to approx. 5° C./min) of the coated semiconductor component in the oven to about room temperature with nitrogen purging, the semiconductor components thus coated are encapsulated with an epoxy resin molding material within approx. 48 hours.

### EXAMPLE 6

The semiconductor component, immediately before the polymer encapsulation, is immersed at an immersion rate of from approx. 0.5 to approx. 2 cm per second first into a solution of from approx. 10 to approx. 30% by weight of polyisocyanate in methyl ethyl ketone and pulled out again, in the course of which the surfaces which are to be unencapsulated later are masked with a Kapton film.

Subsequently, within approx. 30 minutes after the end of the immersion process, a solution of approx. 1% by weight of polybenzoxazole (PBO) in a mixture of approx. 9% by weight of NMP, approx. 40% by weight, approx. 50% by weight of acetone is sprayed onto this polyisocyanate layer, so as to give rise to up to approx. 2 μm of PBO after 25.

After the removal of the Kapton film, this component in the magazine is heated for from approx. 15 to approx. 60 minutes in a nitrogen-purged forced-air oven with a set temperature of from approx. 80 to approx. 100° C. The temperature is then increased to approx. 200° C. at a heating rate of from approx. 3 to approx. 5° C./min and this is kept for at least approx. 30 minutes.

After cooling (cooling rate from approx. 2 to approx. 5° C./min) of the coated semiconductor component in the oven with nitrogen purging to about room temperature, the semiconductor components thus coated are encapsulated with an epoxy resin molding material within approx. 48 hours.

The invention will be described in detail below with reference to working examples corresponding to the drawing.

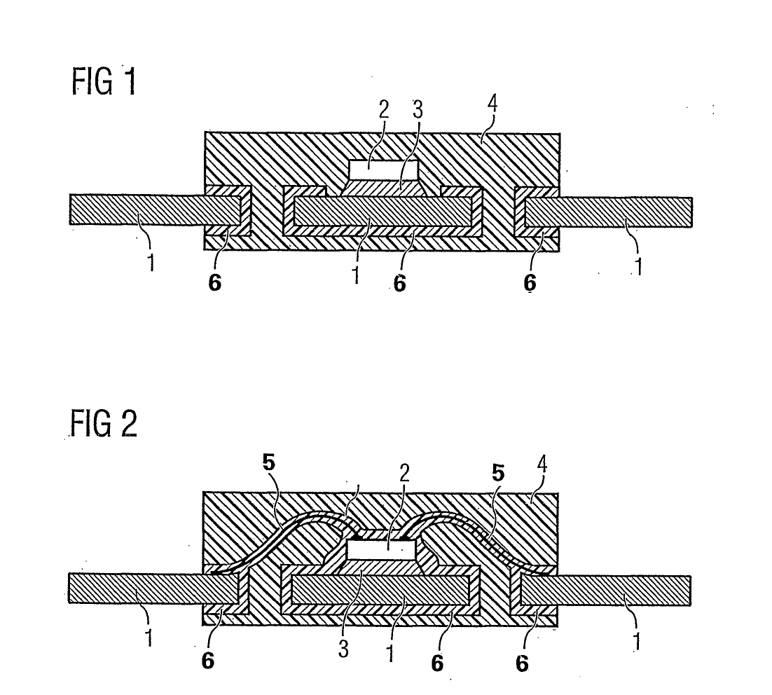

FIG. 1 illustrates a greatly enlarged cross section through a semiconductor component with inventive substrate 1. The drawing is not to scale; the size ratios are reproduced in a distorted manner to clarify the schematic structure. For simplification, the electrical contacts between semiconductor chip 2 and substrate 1 are not illustrated.

According to FIG. 1, the semiconductor component has, in addition to a semiconductor chip 2, a substrate 1 with inventive polymer layer 6. The semiconductor chip 2 is not in direct contact with the substrate 1, but rather is applied to the substrate 1 by means of a securing layer 3.

Semiconductor chip 2 and substrate 1 are surrounded by a polymer material 4. According to FIG. 1, the polymer material 4 is only in direct contact with the substrate 1 in the region of the intermediate space between securing layer 3 and start of the polymer layer 6; at all other points, the polymer material 4 is in direct contact with the polymer layer 6 which envelopes the substrate 1.

FIG. 2 illustrates a greatly enlarged cross section through a semiconductor component within inventive full coating. The drawing is not to scale; the size ratios are reproduced in a distorted manner to clarify the schematic structure. To illustrate the full coating, two wire contacts are additionally drawn in.

According to FIG. 2, the semiconductor component has, in addition to a semiconductor chip 2, wire contacts 5 and a substrate 1, all of which are surrounded by the inventive polymer layer 6.

In contrast to the embodiment of the present invention illustrated in FIG. 1, in the embodiment according to FIG. 2, all elements are covered with the polymer layer 6; there is thus direct contact to the polymer material 4 for none of the elements present in the semiconductor component.

The area covered by the polymer layer 6 on the substrate 1 is dependent upon the requirements of the particular semiconductor component. Various embodiments according to the present invention are conceivable and possible.

In the embodiment illustrated here, the regions of the flat conductor 1 projecting out of the polymer material 4 are not covered with the polymer layer 6 in order to enable the semiconductor component to be soldered in.

This selective coating of the flat conductor 1 with the polymer layer 6 can be achieved by masking the regions which are not to be coated in the course of performance of the immersion or spray coating to obtain the polymer layer 6. In addition, it is possible to carry out a selective coating of the flat conductor 1 with the polymer layer 6 by highly selective spraying only of the regions to be coated by a spray process with defined nozzle arrangement, nozzle size, spraying time and/or pressure.

In a further embodiment which is likewise not illustrated, that region of the flat conductor 1 on which the semiconductor chip 2 is secured is also covered with the polymer layer 6. This is possible when no conducting connection between semiconductor chip 2 and chip island is required and it is possible to dispense with selective coating.

What is claimed is:

1-24. (canceled)

25. A semiconductor housing comprising:
a leadframe which is intended to be equipped with a semiconductor chip and to be enveloped with a polymer material; and
a polymer layer applied as an adhesive layer to the leadframe and having end groups which are aligned toward the polymer material and end groups which are aligned toward a flat conductor, and the polymer layer comprising at least one polymer from the group of the fluorinated polyimides, the polyisocyanates, the polyamidocarboxylic esters of the polyamide-silicone block copolymers, the polyamide imides having silanes in the polymer chain or the polyimide-silicone copolymers having silanes in the copolymer chain.

26. The semiconductor housing of claim 1, wherein the polymer layer comprises a fluorinating polyimide, and, to this end, a 10 percent by weight solution of a polyimide, composed of 2,2-bis[phenyl-3′,4′-dicarboxylic anhydride]-1,1,1,3,3,3-hexafluoropropylene and 3,3′,5,5′-tetramethyl-4-,4′-diaminodiphenylmethane in γ-butyrolactone or NMP and cyclopentanone with a γ-butyrolactone or NMP:cyclopentanone weight ratio=1:2, is applied to the semiconductor component before the encapsulation process, selectively without spraying of the outer connecting pins and of the heatsink plate, with a suitable dispensing apparatus, in such a way that a layer thickness d where 0.05 μm≦d≦5 μm is realized after the heat treatment process which follows.

27. The semiconductor housing of claim 1, wherein the adhesive layer comprises polyamide imide whose acid groups have been condensed with amino groups of a silane, each 2nd to 10th free acid group of the polyamide imide having reacted chemically with an amino group of a silane.

28. The semiconductor housing of claim 1, wherein the adhesive layer comprises a polyimide amide-silicone copolymer having silanes in the polymer chain, acid groups of the polyamide imide having been condensed with amino groups of a silane and every 2nd to 10th free acid group of the polyamide imide having reacted chemically with an amino group of a silane.

29. The semiconductor housing of claim 1, wherein the polymer layer additionally comprises one or more of the following substances:
imidazoles;
liquid-crystalline polymers;
high-temperature-resistant thermoplastics;
phenol resins;
amino resins;
siloxanes;
unsaturated polyesters;
polybenzoxazoles;
polybenzimidazoles;
epoxides;
polyurethanes;
polymers with sulfur in the main chain; and
polymers with sulfur in the side chain.

30. The semiconductor housing of claim 1, wherein the polymer layer has, in the main chains and/or side chains, additionally one or more of the following functional groups:
sulfone group;
mercapto group;
amino group;
carboxyl group;
cyano group;
keto group;
hydroxyl group;
silano group; and
titano group.

31. The semiconductor housing of claim 1, wherein the polymer precursor comprises one or more copolymers.

32. The semiconductor housing of claim 1, wherein the polymer precursor comprises a mixture of two or more polymers.

33. The semiconductor housing of claim 1, wherein the polymer layer has one or more plies, each ply comprising one or more polymers.

34. The semiconductor housing of claim 1, wherein the polymer layer comprises one or more of the following assistants:
solvents;
adhesion promoters;
antioxidants;
catalysts;
reinforced fillers;
plasticizers; and
UV stabilizers.

35. A semiconductor comprising:
an unencapsulated semiconductor component which is provided with a polymer material to envelope it; and
a polymer layer being applied to the unencapsulated semiconductor component and having end groups which are aligned toward the polymer composition and end groups which are aligned toward the flat conductor, wherein the polymer layer comprises at least one polymer from the group of the fluorinated polyimides, the polyisocyanates, the polyamidocarboxylic esters of the polyamide-silicone block copolymers, the polyamide imides having silanes in the polymer chain or the polyimide-silicone copolymers having silanes in the copolymer chain.

36. The semiconductor of claim 35, wherein the polymer layer additionally comprises one or more of the following substances:
imidazoles;
liquid-crystalline polymers;
high-temperature-resistant thermoplastics;
phenol resins;
amino resins;
siloxanes;
unsaturated polyesters;
polybenzoxazoles;
polybenzimidazoles;
epoxides;
polyurethanes;
polymers with sulfur in the main chain; and
polymers with sulfur in the side chain.

37. The semiconductor of claim 35, wherein the polymer precursor comprises one or more copolymers.

38. The semiconductor of claim 35, wherein the polymer precursor comprises a mixture of two or more polymers.

39. The semiconductor of claim 35, wherein the polymer layer has one or more plies, each ply comprising one or more polymers.

40. The semiconductor of claim 35, wherein the polymer layer comprises one or more of the following assistants:
solvents;
adhesion promoters;
antioxidants;
catalysts;
reinforced fillers;
plasticizers; and
UV stabilizers.

41. The semiconductor of claim 35, wherein the semiconductor component has a semiconductor chip and an envelope of a polymer material.

42. A process for producing a leadframe which is intended to be equipped with a semiconductor chip and to be enveloped with a polymer material, comprising:
providing a substrate and/or an unencapsulated semiconductor component;
applying a suspension or a polymer precursor to the substrate and/or the unencapsulated semiconductor component; and
obtaining a polymer layer by evaporating a solvent or by polymerizing the polymer precursor, the polymer layer comprising at least one polymer from the group of the fluorinated polyimides, the polyisocyanates, the polyamidocarboxylic esters of the polyamide-silicone block copolymers, the polyamide imides having silanes in the polymer chain or the polyimide-silicone copolymers having silanes in the copolymer chain.

43. The process of claim 42, comprising:
applying a 10 percent by weight solution of a polyimide, composed of 2,2-bis[phenyl-3′,4′-dicarboxylic anhydride]-1,1,1,3,3,3-hexafluoropropylene and 3,3′,5,5′-tetramethyl-4,4′-diaminodiphenylmethane in γ-butyrolactone (or NMP) and cyclopentanone in a γ-butyrolactone (or NMP):cyclopentanone weight ratio=1:2, selectively to the semiconductor component before the encapsulation process, in that the component thus coated is then heated from room temperature to 200° C. in a nitrogen-purged oven using a temperature ramp (2-5° C./min), and in that the component is then cooled at 200° C. for 60 minutes with evaporation of the solvent from the coating solution and enveloped with an encapsulating material composed of epoxy resin.

44. The process of claim 42, comprising:
admixing 20 percent by weight solution of polyamide imide (PAI) with from 0.1 to 1 percent by weight of 3-aminopropyltrimethoxysilane in dimethylacetamide, NMP or γ-butyrolactone, and stirred at 80° C. for 2 hours, so that the amino groups of the silane condense with the acid groups of the PAI in such a way that,depending on the amount of silane added, approx. every 2nd to 10th free acid group of the PAI reacts chemically with an amino group of a silane, in that the solution thus obtained is then diluted in any desired manner with cyclopentanone, anisole, acetone or similar solvents to a concentration of approx. 5 percent by weight (based on the silane-modified PAI), in that this solution is applied selectively to the semiconductor component before the encapsulation process,in that the component thus coated is heated from room temperature to 200° C. in a nitrogen-purged oven using a temperature ramp (2-5° C./min) and is kept at 200° C. for 60 minutes with evaporation of the solvent, and in that the component is finally enveloped with an encapsulating material composed of epoxy resin.

45. The process of claim 42, comprising:
obtaining a polyimide-silicone copolymer having silanes in the polymer chain by selectively applying a polymer prepared with silanes and composed of silicone and polyamide imide as an approx. 5 percent by weight solution in NMP, cyclopentanone and acetone in a mass ratio of the solvents: NMP:cyclopentanone:acetone=approx. 1:2:2 to the semiconductor component before the encapsulation process, and in that a heat treatment process is carried out in which the component thus coated is heated from room temperature to 200° C. in a nitrogen-purged oven using a temperature ramp (2-5° C./min) and is kept at 200° C. for 60 minutes with evaporation of the solvent, and in that, after the component has been cooled to about room temperature, the component is enveloped with the encapsulating material composed of epoxy resin.

46. The process of claim 42, comprising:
diluting a polyamidocarboxylic acid dissolved in from approx. 50 to approx. 90% by weight of N-methylpyrrolidone (NMP) and esterified with diethylene glycol methacrylate (polycondensed from the monomers pyromellitic anhydride and 4,4′-oxydianiline) with cyclopentanone in a ratio of approx. 1:20, in that this solution is mixed further with acetone or ethanol in a ratio of approx. 1:1, in that as a still unencapsulated semiconductor component is immersed into this solution for contacting of the semiconductor chip and its wires at an immersion rate of from approx. 0.5 to approx. 5 cm per second and pulled out again, in that the semiconductor component thus coated is subsequently stored in a magazine at about room temperature for from approx. 5 to approx. 500 minutes, in that this unencapsulated semiconductor component is then positioned for from approx. 15 to approx. 60 minutes in a forced-air oven under a flow of at least approx. 20 l/min of nitrogen with a set temperature of from approx. 80 to approx. 100° C., in that the temperature is then increased to approx. 250° C. with a heating rate of from approx. 3 to approx. 5° C./min and is kept for at least approx. 60 minutes, and in that, after cooling (cooling rate from approx. 2 to approx. 5° C./min) of the coated semiconductor component in the oven with nitrogen purging to about room temperature, the semiconductor components thus coated are encapsulated with an epoxy resin molding material within approx. 48 hours.

47. The process of claim 42, comprising:
admixing a solution of a polyamidocarboxylic ester with an NMP/cyclopentanone/acetone mixture with approx. 10% (based on the weight of pure polyamidocarboxylic ester) of N-(3-(trimethoxysilyl)propyl)ethylenediamine and stirred at approx. 120° C. for approx. one hour, in that, in the course of this, the silane is polycondensed with another silane to give the silicone and, simultaneously with its amino group, partly with the acid groups of the polyamidocarboxylic acid to give the polyamide-silicone block copolymer, and secondly, with its amino group, partly with the acid groups of the polyamidocarboxylic acid, once the diethylene glycol methacryloyl side chains have been eliminated, to give the silane- or silicone-modified polyimide precursor, in that the solution thus prepared, after the contacting with the semiconductor chip and wire, is applied to the unencapsulated semiconductor component, in that the component thus coated is then stored in a magazine at about room temperature for from approx. 5 to approx. 500 minutes, in that this component is then positioned for from approx. 15 to approx. 60 minutes in a forced-air oven with purging with at least approx. 20 l/min of nitrogen at a set temperature of from approx. 80 to approx. 100° C., in that the temperature is then increased to approx. 250° C. at a heating rate of from approx. 3 to approx. 5° C./min and this is kept for at least approx. 60 min; in that, after cooling (cooling rate from approx. 2 to approx. 5° C./min) of the coated semiconductor component in the oven with nitrogen purging to about room temperature, the semiconductor components thus coated are encapsulated with an epoxy resin molding material within approx. 48 hours.

48. The process of claim 42, comprising:
immersing the semiconductor component, immediately before the polymer encapsulation, at an immersion rate of from approx. 0.5 to approx. 2 cm per second first into a solution of from approx. 10 to approx. 30% by weight of polyisocyanate in methyl ethyl ketone and pulled out again, in the course of which the surfaces which are to be unencapsulated later are masked with a Kapton film, in that, within approx. 30 minutes after the end of the immersion process, a solution of approx. 1% by weight of polybenzoxazole (PBO) in a mixture of approx. 9% by weight of NMP, approx. 40% by weight, approx. 50% by weight of acetone is then applied to this polyisocyanate layer, in that, after removal of the Kapton film, this component in the magazine is heated for from approx. 15 to approx. 60 minutes in a nitrogen-purged forced-air oven with a set temperature of from approx. 80 to approx. 100° C., in that the temperature is then increased to approx. 200° C. at a heating rate of from approx. 3 to approx. 5° C./min and is kept for at least approx. 30 minutes, and in that, after cooling (cooling rate from approx. 2 to approx. 5° C./min) of the coated semiconductor component in the oven with nitrogen purging to about room temperature, the semiconductor component thus coated is encapsulated with an epoxy resin molding material within approx. 48 hours.

49. A structure comprising:
a leadframe; and
means for equipping the leadframe with a semiconductor chip and to be enveloped with a polymer material, a polymer layer being applied as an adhesive layer to the leadframe and having end groups which are aligned toward the polymer material and end groups which are aligned toward the flat conductor, and the polymer layer comprising at least one polymer from the group of the fluorinated polyimides, the polyisocyanates, the polyamidocarboxylic esters of the polyamide-silicone block copolymers, the polyamide imides having silanes in the polymer chain or the polyimide-silicone copolymers having silanes in the copolymer chain.

50. The structure of claim 49, further comprising the semiconductor chip.
